(19) United States
(12) Patent Application Publication
(10) Pub. No.: US 2020/0024729 A1
(43) Pub. Date: Jan. 23, 2020

(54) Grain Size Tuning for Radiation Resistance

(71) Applicants: Mitra Lenore Taheri, Philadelphia, PA (US); Greg Vetterick, Seattle, WA (US)

(72) Inventors: Mitra Lenore Taheri, Philadelphia, PA (US); Greg Vetterick, Seattle, WA (US)

(73) Assignee: Drexel University, Philadelphia, PA (US)

(21) Appl. No.: 16/224,302

(22) Filed: Dec. 18, 2018

Related U.S. Application Data
(63) Continuation of application No. 15/102,425, filed on Jun. 7, 2016, now abandoned.
(60) Provisional application No. 61/921,219, filed on Dec. 27, 2013.

(51) Int. Cl. C23C 14/58; C23C 14/16; C23C 14/34; C23C 14/35; C23C 14/54

(52) U.S. Cl. CPC C23C 14/5806; C23C 14/16; C23C 14/541; C23C 14/351; C23C 14/345

(57) ABSTRACT

A process for producing a radiation resistant nanocrystalline material having a polycrystalline microstructure from a starting material selected from metals and metal alloys. The process including depositing the starting material by physical vapor deposition onto a substrate that is maintained at a substrate temperature from about room temperature to about 850° C. to produce the nanocrystalline material. The process may also include heating the nanocrystalline material to a temperature of from about 450° C. to about 800° C. at a rate of temperature increase of from about 2° C./minute to about 30° C./minute; and maintaining the nanocrystalline material at the temperature of from about 450° C. to about 800° C. for a period from about 5 minutes to about 35 minutes. The nanocrystalline materials produced by the above process are also described. The nanocrystalline materials produced by the process are resistant to radiation damage.

This application is a continuation of application Ser. No. 15/102,425 filed on Jun. 7, 2016, which is a 371 continuation of International patent application no. PCT/US2014/071932 filed on Dec. 22, 2014, which, in turn, claims the benefit of U.S. provisional application No. 61/921,219, filed on Dec. 27, 2013, the contents of these applications are herein incorporated by reference in their entirety.

This invention was made with government support under Grant No. DE-SC0008274.df awarded by the Department of Energy Basic Energy Sciences. The government has certain rights in the invention.

### BACKGROUND OF THE INVENTION

### 1. Field of the Invention

The present invention is directed to the field of nanocrystalline materials. In particular, the present invention is directed to a process of manufacturing an ultra-fine grain size nanocrystalline material that is resistant to radiation damage.

### 2. Description of the Related Technology

Materials used in conditions exposed to high energy radiation such as in nuclear reactors and in space are susceptible to radiation damage caused by energetic collision of particles (e.g. neutrons, protons, or electrons) with the atoms in the crystal structure of the material. These collisions displace atoms from their equilibrium positions, thereby damaging the internal structure of the material and affecting the properties that result from that microstructure.

Spacecraft and their occupants are subjected to irradiation by cosmic rays, a term that collectively describes the high energy particles traveling through space at nearly the speed of light. Cosmic radiation primary consists of protons with energies in the range of 100 MeV (protons at 43% of the speed of light) and 10 GeV (protons at 99.6% of the speed of light). Due to their high energy, these particles have damaging effects on both the spacecraft and the human body and are a major concern when considering long term space travel (e.g. a trip to Mars). Materials used in a spacecraft must be lightweight and able to perform their intended function without interruption. Structural materials must provide adequate shielding of the occupants and equipment inside the shuttle, and maintain their mechanical properties throughout the mission. Radiation tolerant electronic materials (i.e. solar panels and computer chips) must operate in the same environment without errors.

The core of a nuclear reactor is particularly vulnerable to radiation damage. For example, a structural component in the core of a pressurized water reactor is exposed to somewhere on the order of 10²³ neutron collisions per square centimeter over their 40 year lifetime. The neutrons may possess energy up to several hundred MeV, sufficient to cause significant damage in the reactor. Damage accumulated is measured in displacements per atom (DPA) where 1 dpa signifies that every atom in the structure has been displaced from its equilibrium position one time on average. Current light water reactor designs receive damage of 5-10 dpa, and future reactor designs may see upwards of 500 dpa in structural materials around the reactor core.

The collisions with neutrons result in a non-equilibrium concentration of interstitial and vacancy point defects. Interaction among these point defects in the material leads to significant changes in chemistry (e.g. segregation of alloying elements by diffusion), mechanical properties (e.g. radiation hardening from accumulation of point defects into dislocation loops), and physical dimensions (e.g. vacancies clustering as voids leading to swelling) of the structural materials.

Point defects in materials may be mitigated by engineering grain boundaries in the material using a combination of processes including spontaneous loss of defects from cascades at the boundary, annihilation of defects in the bulk of the material via emission of atoms from grain boundaries, and diffusion of freely mobile defects to the boundary. In addition, grain boundary sinks may also reduce the amount of damage occurring from interstitial and vacancy clustering in the structural materials. Efforts to provide radiation resistant materials have led to discovery of new materials with variety of grain sizes and grain boundary characteristics, such as nanocrystalline materials.

Recently, nanocrystalline materials, especially nanocrystalline films, have been used in a wide range of applications for their increased hardness, high strength, ductility, and fatigue resistance. Ö. Altun & Y. E. Böke, “Effect of the Microstructure of EB-PVD Thermal Barrier Coatings on the Thermal Conductivity and the Methods to Reduce the Thermal Conductivity,” Arch. Mat. Sci. Engineering, vol. 40, pages 47-52 (2009) teaches use of electron beam physical vapor deposition to lay ceramic thermal barrier coatings onto turbine blades with desired microstructures in the coatings. The microcrystalline structure varies with the thickness of the coating, which is generally in the range of 50 μm to 350 μm.

US 2008/0135914 A1 discloses a process for making a metallic nanocrystalline layer on a substrate. The process involves steps of pretreating the substrate to make its surface smoother in order to prevent non-uniform nucleation; physical vapor deposition of a metal layer on the substrate; and annealing the metal layer at a temperature from 300 to 1250° C. Prior to physical vapor deposition, the substrate may be pre-heated to a temperature from 300 to 1250° C. The metal may be selected from nickel, platinum, gold, etc. The nanocrystalline layer may have a grain size within a range from about 0.5 nm to about 10 nm.

U.S. Pat. No. 6,436,825 B1 discloses a method of making a copper barrier layer for semiconductor integrated circuit devices. The method includes the steps of physical vapor deposition sputtering of a material to form a copper metal diffusion barrier layer; treating the barrier layer with a silane gas plasma; and thermally annealing the barrier layer to drive silicides into the barrier layer. The material for the barrier layer may be TaN, Ta, TiN or WN. The physical vapor deposition is carried out under a pressure of from 0.01 to 100 mTorr. The annealing temperature is dependent on the material, and generally is in the range of from 450 to 900° C.

WO 2012/092061 A2 discloses a method for making a graphene-based device. The method involves the steps of physical vapor deposition using a graphite source onto an ionic substrate having a dielectric formed thereon; followed by annealing the substrate at a temperature of at least 1000° K. The deposition step may be performed in Ar plasma at a temperature ranging from room temperature to a higher temperature.

Carlos Ziebert et al. “Sputter Deposition of Nanocrystalline β-SiC Films and Molecular Dynamics Simulations of the Sputter Process,” J. Nanosci. Nanotechnol., vol. 10, pages 1120-1128 (2010) discloses a process of making corrosion and wear resistant silicon-carbide thin films. The method involves heating a substrate to a temperature of from 100 to 900° C., and depositing silicon-carbide material onto the substrate via sputtering process. The films were characterized by electron probe micro-analysis, X-ray diffraction, Raman spectroscopy and atomic force microscopy.

The present invention provides a process to tune the grain size, texture and/or grain boundary character of nanocrystalline materials, which allows the provision of nanocrystalline materials with small grain sizes and desirable grain boundary characteristics. Such nanocrystalline materials, especially nanocrystalline films, are resistant to radiation damage.

### SUMMARY OF THE INVENTION

In one aspect, the present invention provides a process for producing a radiation resistant nanocrystalline material having a polycrystalline microstructure from a starting material selected from the group consisting of carbides, ceramics, silicon, ionic materials, polymers, oxides, metals, metal alloys and salts, the process comprising steps of depositing the starting material by physical vapor deposition onto a substrate configured to prevent formation of a single crystal film on the substrate and maintained at a substrate temperature from about room temperature to about 850° C. to produce the nanocrystalline material.

In another aspect, the present invention provides a process for depositing the starting material by physical vapor deposition onto a substrate selected from the group consisting of carbides, ceramics, silicon, ionic materials, polymers, oxides, metals, metal alloys and salts.

In yet another aspect, the present invention provides a process further comprising the steps of heating the nanocrystalline material to a temperature sufficient to recovery or grain growth in the material from about room temperature to about 2500° C. at a rate of temperature increase of from about 2° C./minute to about 50° C./minute; and maintaining the nanocrystalline material at the temperature of from about room temperature to about 2500° C. for a period from about 5 minutes to about 60 minutes.

In another aspect, the present invention provides nanocrystalline materials prepared by the above processes.

In yet another aspect, the present invention provides a nanocrystalline material with a grain size of from about 10 nm to about 150 nm.

These and various other advantages and features of novelty that characterize the invention are pointed out with particularity in the claims annexed hereto and forming a part hereof. However, for a better understanding of the invention, its advantages, and the objects obtained by its use, reference should be made to the drawings which form a further part hereof, and to the accompanying descriptive matter, in which there is illustrated and described a preferred embodiment of the invention.

### BRIEF DESCRIPTION OF THE DRAWINGS

The application file contains at least one drawing executed in color. Copies of this patent application publication with color drawings will be provided by the Office upon request and payment of the necessary fee.

FIG. 1 is a flow chart on a process of producing a radiation resistant nanocrystalline material according to one embodiment of the present invention.

FIGS. 2A and 2B are transmission electron microscopy (TEM) images showing dislocation loops in materials after exposure to radiation sufficient for 5 dpa (displacements per atom). A material with a grain size over 500 μm is depicted in FIG. 2A and a material with a grain size under 300 nm is depicted in FIG. 2B.

FIG. 3A is a TEM image showing dislocation loops in a nanocrystalline film with a grain size of 100 nm after exposure to radiation sufficient for 0.5 dpa.

FIG. 3B is a TEM image showing dislocation loops in a nanocrystalline film with a grain size of 200 nm after exposure to radiation sufficient for 0.5 dpa.

FIG. 4 is a series of video frames showing the process of dislocation loop formation and subsequent absorption by a grain boundary in a nanocrystalline film after exposure to radiation (time in minutes).

FIG. 5 is a cross-sectional view of a nanocrystalline iron film showing a columnar grain structure with random high angle grain boundaries and a grain diameter of 20-100 nm.

FIG. 6A is a TEM image showing dislocation loops formed in a polycrystalline iron film with 100 nm<grain size<1 μm after irradiation sufficient for 5 dpa at 300 C°.

FIG. 6B is a TEM image showing dislocation loops formed in a free-standing ultrafine grain iron film with a grain size of ˜500 nm after irradiation sufficient for 5 dpa at 300 C°.

FIG. 6C is a TEM image showing dislocation loops formed in a nanocrystalline ion film with a grain size of 15-100 nm after irradiation sufficient for 5 dpa at 300 C°.

FIG. 7A shows a correlation between dislocation loop size and grain size in nanocrystalline films after exposure to radiation.

FIG. 7B shows a correlation between dislocation cluster density and grain size in nanocrystalline films after exposure to radiation sufficient for 5 dpa at 300 C°.

FIGS. 8A-8C show the denuded zone effect in the following pure iron materials: polycrystalline (FIG. 8A), ultrafine grain (FIG. 8B), and nanocrystalline grains (FIG. 8C).

FIG. 9A is a brightfield TEM image of a grain in a nanocrystalline pure iron film showing the concentration of dislocation loops along grain boundaries.

FIG. 9B is a pole figure map of FIG. 9A acquired by NanoMEGAS ASTAR orientation mapping in the TEM.

FIG. 10 shows a series of TEM images depicting reduced radiation damage in small grains after exposure to radiation at different dosages up to 20 dpa.

FIG. 11A shows the grain structure of a nanocrystalline film produced by Deposition B in Example 5, as observed in out of plane orientation.

FIG. 11B shows the grain structure of a nanocrystalline film produced by Deposition B in Example 5, as observed by TEM brightfield.

FIG. 12A shows the grain structure of a nanocrystalline film produced by Deposition C in Example 5, as observed in out of plane orientation.

FIG. 12B shows the grain structure of a nanocrystalline film produced by Deposition C in Example 5, as observed by TEM brightfield.

FIG. 13A shows a reflection high-energy electron diffraction (RHEED) pattern of (100) NaCl substrates before a 450° C. anneal and 5 minute argon ion cleaning.

FIG. 13B is an RHEED pattern of 001 NaCl substrates after the 450° C. anneal and 5 minute argon ion cleaning.

FIG. 14A shows the grain structure of a nanocrystalline film deposited on the cleaned substrate of FIG. 13B, as observed in out of plane orientation.

FIG. 14B shows the grain structure of a nanocrystalline film deposited on the cleaned substrate of FIG. 13B, as observed by TEM brightfield.

### DETAILED DESCRIPTION OF THE PREFERRED EMBODIMENT(S)

For illustrative purposes, the principles of the present disclosure are described by referencing various exemplary embodiments. Although certain embodiments are specifically described herein, one of ordinary skill in the art will readily recognize that the same principles are equally applicable to, and can be employed in other systems and methods. Before explaining the disclosed embodiments of the present disclosure in detail, it is to be understood that the disclosure is not limited in its application to the details of any particular embodiment shown. Additionally, the terminology used herein is for the purpose of description and not of limitation. Furthermore, although certain methods are described with reference to steps that are presented herein in a certain order, in many instances, these steps may be performed in any order as may be appreciated by one skilled in the art; the novel method is therefore not limited to the particular arrangement of steps disclosed herein.

It must be noted that as used herein and in the appended claims, the singular forms “a”, “an”, and “the” include plural references unless the context clearly dictates otherwise. Furthermore, the terms “a” (or “an”), “one or more” and “at least one” can be used interchangeably herein. The terms “comprising”, “including”, “having” and “constructed from” can also be used interchangeably.

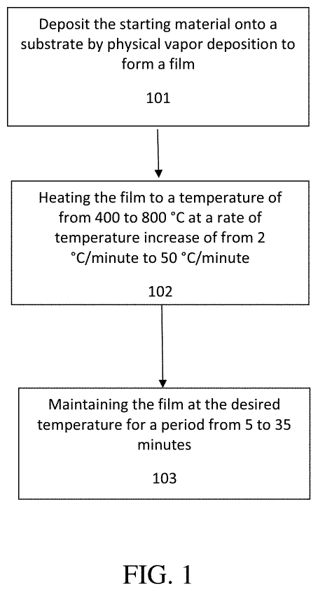

The present invention provides a process for tuning grain size of a nanocrystalline material, such as a nanocrystalline film, for enhancing resistance to radiation damage. Referring to FIG. 1, the process produces a radiation resistant nanocrystalline material from a starting material selected from the group consisting of carbides, ceramics, silicon, ionic materials, polymers, oxides, metals, metal alloys and salts. The process of the present invention is aimed at producing a polycrystalline microstructure in nanocrystalline film, comprising steps of in step 101 depositing the material onto a substrate by physical vapor deposition to form a film on the substrate; in step 102 heating the formed film to a temperature of from about 100° C. to about 2700° C., at a rate of temperature increase of from about 2° C./minute to about 50° C./minute; and in step 103 maintaining the film at the temperature of from about 100° C. to about 2700° C. for a period from about 5 minutes to about 60 minutes. More preferably, the formed film is heated to a temperature of from about 450° C. to about 800° C. at a rate of temperature increase of from about 2° C./minute to about 30° C./minute; and maintaining the film at the temperature of from about 450° C. to about 800° C. for a period from about 5 minutes to about 35 minutes.

To ensure production of the polycrystalline microstructure in the nanocrystalline film, one or more of the following parameters may be adjusted: substrate selection, substrate temperature, deposition speed, deposition pressure, deposition gas flow at substrate, deposition gas flow at vapor source.

The nanocrystalline material is selected from the group consisting of carbides, ceramics, silicon, ionic materials, polymers, oxides, salts, and metals and alloys. When an alloy is used, the alloy may comprise alloying elements designed to stabilize the microstructure at high temperature and under high doses of radiation, as well as to provide increased radiation and corrosion resistance for the nanocrystalline materials. Such alloying elements can be selected from the group consisting of Cr, Ni, Mn, P, S, Si, Co, Al, Zr, Hf, and W. Examples of suitable nanocrystallline materials include Fe, Fe—Zr, Cu, Cu—Ni, Cu—Li, Al—Li, Mo—Re, Fe—Cr—Ni, austenitic stainless steel, zirconium alloys (zircalloy) and nickel based alloys.

The selection of substrate influences the production of radiation resistant nanocrystalline material. The substrate may be configured so that it does not readily permit the formation of a single crystal film. In some embodiments, the physical vapor deposition parameters may be adjusted to overcome preferential nucleation on a substrate that may lead to formation of a single crystal film.

Any suitable substrate for deposition may be used in the present invention. Some examples of suitable substrates include carbides, ceramics, silicon, and ionic materials such as NaCl, as well as polymers, oxides, metals, salts. Further, a nanocrystalline material may be deposited on the surface of another base metal such as nanocrystalline austenitic stainless steel on a low alloy steel monolith.

The substrate may be pretreated to expose a fresh surface on which the material may be deposited. One technique for exposing a fresh surface is to cleave the substrate shortly before placing it into a deposition chamber. Another technique may employ energetic ion bombardment remove surface contamination. The substrate may also be pretreated to make its surface smoother in order to prevent or minimize non-uniform nucleation and facilitate separation of the formed film from the substrate.

The substrate may be heated during the deposition step. In some embodiments, the substrate is held at a temperature of from room temperature to about 850° C., or from about 100° C. to about 700° C., or from about 300° C. to about 600° C., or from about 400° C. to about 500° C., or from about 400° C. to about 425° C., during the deposition step. Annealing may not be required depending on the substrate that is selected. For example, annealing is useful for an NaCl substrate but for other substrates annealing may have little effect on the deposition.

The material may be deposited onto a substrate by physical vapor deposition (FIG. 1) or any other suitable method. In some embodiments, the material may be deposited on the surface of a base material, for example, nanocrystalline austenitic stainless steel may be deposited on a low alloy steel monolith.

The physical vapor deposition method may be selected from electron beam physical vapor deposition, magnetron sputtering physical vapor deposition, pulsed laser physical vapor deposition, thermal evaporation physical vapor deposition, or combinations thereof. The physical vapor deposition may be carried out at a pressure from about 0.01 mTorr to about 100 mTorr, or from about 0.1 mTorr to about 50 mTorr, or from about 0.1 mTorr to about 30 mTorr. In some embodiments, physical vapor deposition is carried out to achieve a growth rate of the film at from about 0.5 Å/sec to about 5 Å/sec, or from about 0.5 Å/sec to about 3.5 Å/sec, or from about 1 Å/sec to about 3 Å/sec, or from about 1.5 Å/sec to about 2 Å/sec. These ranges are particularly useful for deposition of iron on NaCl. These parameters can be adjusted for other deposition materials and/or substrates, as required.

The physical vapor deposition process may employ a deposition chamber with inert gas, such as Ar, N₂. The gas in the deposition chamber may create a gas flow to improve deposition. The gas flow at the metal or alloy (target) in the deposition chamber may be from about 0 sccm to about 50 sccm, or from about 10 sccm to about 45 sccm, or from about 20 sccm to about 40 sccm, or from about 25 sccm to about 35 sccm, or from about 28 sccm to about 32 sccm. The gas flow at the substrate in the deposition chamber may be from about 0 sccm to about 20 sccm, or from about 1 sccm to about 15 sccm, or from about 1 sccm to about 10 sccm, or from about 2 sccm to about 8 sccm, or from about 2 sccm to about 5 sccm.

When magnetron sputtering deposition is employed with direct current power, the sputtering power may be, for example, from about 0 Watts to about 600 Watts, or from about 50 Watts to about 600 Watts, or from about 100 Watts to about 600 Watts, or from about 200 Watts to about 600 Watts, or from about 300 Watts to about 600 Watts, or from about 350 Watts to about 550 Watts, or from about 400 Watts to about 500 Watts. If radio frequency power is used, the sputtering power may be from about 0 Watts to about 300 Watts, or from about 20 Watts to about 300 Watts, or from about 50 Watts to about 300 Watts, or from about 100 Watts to about 280 Watts, or from about 130 Watts to about 250 Watts, or from about 150 Watts to about 220 Watts, or from about 180 Watts to about 200 Watts. The sputtering bias may be from about 0 Watts to about 5 Watts, or from about 1 Watts to about 5 Watts, or from about 2 Watts to about 4 Watts. These parameters can be adjusted for other deposition materials and/or substrates.

The physical vapor deposition process may be tuned to produce a film with an advantageous grain size and grain boundary characteristics. The grain size in the nanocrystalline film of the present invention may be in the range from about 10 nm to about 150 nm, or from about 10 nm to about 100 nm, or from about 2 to about 50 nm. The film formed by the deposition step preferably has a uniform thickness. The thickness of the film may be in the range from about 10 nm to about 200 nm, or from about 10 nm to about 100 nm, or from about 10 nm to about 60 nm, or from about 10 nm to about 40 nm. The texture may be controlled to acquire grain boundaries with desirable structure for the intended application.

Referring to FIG. 1, the next step after the deposition step involves heating the formed film to a temperature of from about 100° C. to about 2000° C. The heating of the formed film may also occur at a temperature from formed film to a temperature of from about 450° C. to about 800° C., or from about 475° C. to about 650° C., or from about 500° C. to about 600° C. This heating of the formed film may be carried out in situ (heating the film on the substrate), or ex situ (after the film is separated from the substrate). The maximum temperature during the heating step may be used to control the microstructure of the film including, for example, the grain size.

In some embodiments, the rate of temperature increase may be in the range from about 2° C./min to about 50° C./min, or from about 5° C./min to about 35° C./min, or from about 10° C./min to about 25° C./min.

After the film is heated to the desired temperature, the next step involves maintaining the film at the desired temperature for a period of from about 5 minutes to about 60 minutes, or from about 8 minutes to about 30 minutes, or from about 10 minutes to about 20 minutes, or from about 13 minutes to about 18 minutes (FIG. 1). Annealing of the nanocrystalline material is capable of fine tuning the grain size in the nanocrystalline material, reducing the residual strain in the nanocrystalline material, and eliminating nonequilibrium vacancy concentration produced by the physical vapor deposition technique.

One or both of heating step and maintaining step may be carried out in a special atmosphere to prevent oxidation of the film surface. The special atmosphere may be, for example, an endothermic gas (a mixture of carbon monoxide, hydrogen gas, and nitrogen gas), or a mixture of hydrogen and nitrogen, or a hydrogen atmosphere. In some embodiments, one or both of the heating step and maintaining step may be carried out under vacuum in order to prevent oxidation of the film surface, for example, at a pressure of from 1×10⁻⁴ to 5×10⁻⁸ torr.

After the maintaining step, the film may be cooled to a temperature of from about 250° C. to about 350° C., or from about 275° C. to about 325° C., or from about 290° C. to about 310° C. In some embodiments, the film may be cooled to about 25° C. The rate of temperature decrease during the cooling step may be in the range of from about 5° C./min to about 100° C./min, or from about 10° C./min to about 50° C./min, or from about 15° C./min to about 20° C./min.

The process parameters of the present invention may be varied according to the intended application for the produced nanocrystalline materials. Variation of one or more of the above-mentioned process parameters may be employed to fine tune the grain size and grain boundary characteristics of the nanocrystalline materials, which can provide properties that may be customized for specific applications.

One suitable application of the nanocrystalline materials made by the process of the present invention is for nuclear reactor core components. Typically, in this application, radiation damage is initiated as point defects caused by collisions with particles in nuclear reactors such as neutrons. A cluster of point defects may grow into a dislocation loop. Further growth of dislocation loops ultimately leads to voids and swelling of the nanocrystalline material.

The grain size of the nanocrystalline materials of the present invention has a strong influence on the growth of dislocation loops in the material due to irradiation. As the grain size decreases, the growth of dislocation loops after exposure to radiation is significantly reduced (reduced dislocation loop sizes), leading to resistance to radiation damage.

In polycrystalline iron (grain size>1 μm), irradiation to a dose of approximately 5 dpa may cause the material to form a densely entangled dislocation network created by the interaction of growing finger type loops in regions thicker than about 75 nm. In 150 nm thick ultrafine grain materials having a grain size of 1 μm-100 nm, the finger loops may be visible but are significantly smaller in size. The dislocation loops may not grow large enough to form the tangled dislocation network that would otherwise form in the polycrystalline material. In nanocrystalline materials having a grain size of <100 nm, the dislocation loop diameter is even smaller and may decrease even more with a further decrease in grain size. Similar behavior may be found in other materials.

It has been found that the diameter of the dislocation loops in a nanocrystalline material is proportionate to the grain size of the material, because small point defect clusters are less liable to coalesce to form large finger loops as the grain size decreases.

In addition to the size of the dislocation loops, the dislocation loop density in nanocrystalline materials after irradiation is also affected by the grain size of the nanocrystalline materials. At grain sizes of ˜100 nm, the dislocation loop density in the nanocrystalline materials is low and the average size of the defects is relatively large, indicating the presence of the finger type loops. At intermediate grain sizes of about 25 nm-about 75 nm, the density of dislocation loops in the nanocrystalline materials is higher and there is a significant amount of scatter. The average size of the dislocation loops (e.g. about 3 nm to about 12 nm) is much smaller than the dislocation loops in larger grains (e.g. about ˜100 nm). At the smallest grain sizes, the dislocation loop density falls off sharply. For nanocrystalline materials with grain sizes below about 25 nm, the defect cluster concentration decreases and the point defect clusters are even smaller in size (2-4 nm).

The morphology of the dislocation loops in the nanocrystalline materials after irradiation is also affected by the grain size. In some embodiments, the density of small dislocation loops on the order of 2-4 nm in nanocrystalline materials with large grains appears to be higher than the density in nanocrystalline materials with relatively smaller grains after irradiation at the same dose.

Grain boundary density in the nanocrystalline materials of the present invention is another factor that may impact the growth of dislocation loops in the material after exposure to radiation. Small dislocation loops (e.g. about 2-4 nm) formed as a result of overlapping cascade events may hop over distances of up to about 10 nm which ultimately leads them to cooperatively align on habit planes and form strings of small dislocation loops which then coalesce to form fully discernable interstitial dislocation loops. When the density of grain boundaries is higher, these hops are statistically more likely to find a grain boundary and be annihilated. The presence of grain boundaries in close proximity to the aggregating dislocation loops causes the loop strings in the nanocrystalline material of the present invention to be truncated and thus limits the ultimate size of the dislocations loops. In some embodiments, entire loop strings may be lost to grain boundaries. Additionally, diffusion of point defects to grain boundaries during and after the cascade event limits the number of interstices available to cause the growth of loops by negative climb.

The reduction of point defect concentration at the grain boundaries is thought to prevent nucleation of dislocation loops. It is possible that the radiations may be energetic enough to form point defect clusters directly from the collapse of the cascade. Thus, dislocation loops may be formed uniformly across the sample. However, the grain boundaries in these grains may absorb individual point defects thus contributing to a loss of point defect clusters at the grain boundaries, which lead to formation of denuded zones where the nanocrystalline material is free of defects. There may be a direct correlation between grain boundary character and the width of the denuded zone, and therefore the ability of a nanocrystalline material to resist radiation damage. By creating a microstructure with a high density of strong grain boundary sinks that remain stable under irradiation, the nanocrystalline material is capable of being exposed to large amounts of radiation with relatively little change in its properties.

The width of the denuded zone that arises at a grain boundary with a given structure is constant. The result is that as the grain size decreases the denuded zone comprises a larger portion of the grain and the average point defect density is greatly reduced. Thus, nanocrystalline materials with a smaller grain size have a larger portion of the material remaining as denuded zones after irradiation, thereby providing excellent resistance to radiation damage.

The nanocrystalline materials of the present invention have a grain size in the range of from about 10 nm to about 150 nm, or from about 10 nm to about 100 nm, or from about 2 to about 50 nm. The nanocrystalline materials produced by the process of the present invention have grain size and grain boundary characteristics that give the nanocrystalline materials desired defect annihilation properties. The nanocrystalline materials are suitable for structural materials or as a surface coating for components used in a nuclear reactor or other devices that may be exposed to radiation in order resist material degradation due to radiation.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

### EXAMPLES

The following examples are illustrative, but not limiting, of the methods and compositions of the present disclosure. Other suitable modifications and adaptations of the variety of conditions and parameters normally encountered in the field, and which are obvious to those skilled in the art, are within the scope of the disclosure.

### Example 1

A nanocrystalline ion film with a thickness of 80 nm was deposited at growth rate of 2.0 Å/second on polished (100) NaCl substrates held at 425° C. using electron beam physical vapor deposition. The films were transferred to TEM grids for an in situ heat treatment and subsequent irradiation. Each film was heated in situ immediately before irradiation using a Gatan double tilt heating holder. During the heat treatment, the films were slowly heated to 500° C., allowing time for sample drift and temperature equilibrium. After reaching 500° C., the films were held for 15 minutes at that temperature before the temperature was lowered to 300° C. for the irradiation step.

At a film growth rate of 2.0 Å/second on a 425° C. substrate, iron deposits as columnar grains with a size range of from 20-100 nm. Selected area diffraction spacings were within ˜2% of theoretically perfect BCC (body-centered cubic) iron. Rutherford backscattering spectroscopy indicated that the final film thickness was approximately 70 nm, with a surface layer of iron oxide of less than 10 nm.

### Example 2

The nanocrystalline ion films produced in Example 1 were subjected to irradiation. The iron films were irradiated in situ using a Hitachi H-9000NAR TEM. Each film was stabilized at 300° C. and irradiated with 1 MeV Kr²⁺ ions. Irradiation was performed in segments, pausing only to take still images at doses of: 1×10¹⁴, 2×10¹⁴, 4×10¹⁴, 8×10¹⁴, 1.6×10¹⁵, 2.4×10¹⁵, 3.2×10¹⁵, and 4.0×10¹⁵ ions per square centimeter. This is equivalent to damage levels calculated by SRIM of 0.1, 0.25, 0.5, 1, 2, 3, 4, and 5 dpa, respectively. Imaging was performed using a 200 KV accelerating voltage which was below the knock-on damage threshold for iron. After irradiation, the films were cooled to room temperature at a rate of approximately 30° C./min.

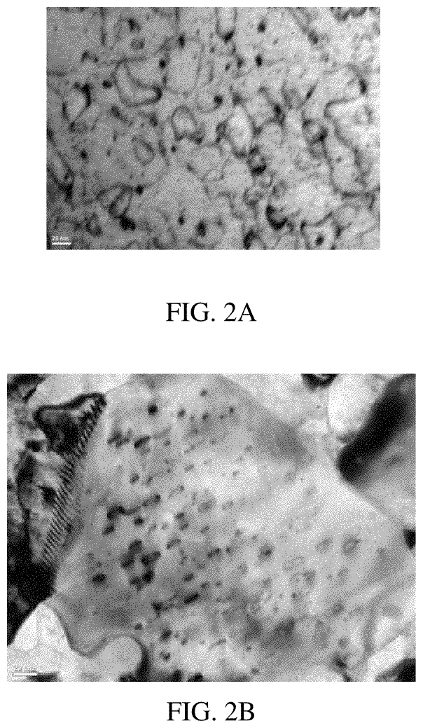

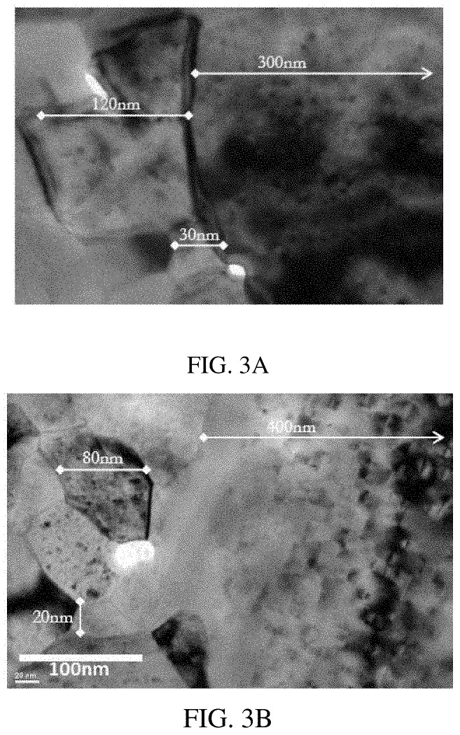

The experimental results showed that the behavior of the irradiated iron nanocrystalline films was very different from that of iron films having micron-sized grains during incubation, steady state growth, and saturation phases of loop growth. In bulk iron with an average grain size above 500 dislocations loops grow continuously until they impinge and form a dislocation network by 5 dpa (FIG. 2A). In contrast, dislocation loops in films with a grain size of 300 nm do not exhibit continuous growth but rather appear to remain stable at 30 nm (FIG. 2B). In the films with a grain size of 200 nm, dislocation loops have diameters at 10-30 nm (FIG. 3B). In nanocrystalline film with grain size of 100 nm, the dislocation loops are primarily on the order of 2-4 nm, indicating that they were unable to organize and coalesce into larger dislocation loops (FIG. 3A)

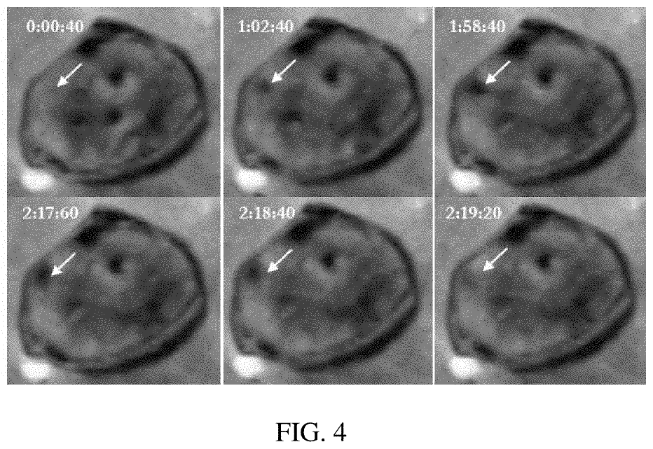

Using means for recording a video of the process of dislocation loop formation near grain boundary of the nanocrystalline film, it was observed that the dislocation loop formation process appeared to be not stable, as showed by video frames in FIG. 4. This observation indicated that the grain boundaries interfere with and inhibit the dislocation loop forming process, making the nanocrystalline film of the present invention resistant to radiation damages.

### Example 3

Materials with different grain sizes were prepared. One material was polycrystalline having a grain size>1 μm, one material was ultrafine having a grain size of from 100 nm to and one material was nanocrystalline having a grain size<100 nm. The polycrystalline films were prepared by conventional twin jet electropolishing from bulk iron while the nanocrystalline and ultrafine grain films were prepared by sputter deposition and then heated to 650° C. to achieve a grain size of 20-150 nm for the nanocrystalline films, or to 850° C. to provide a grain size of 100 nm to 1 μm for the ultrafine grain films.

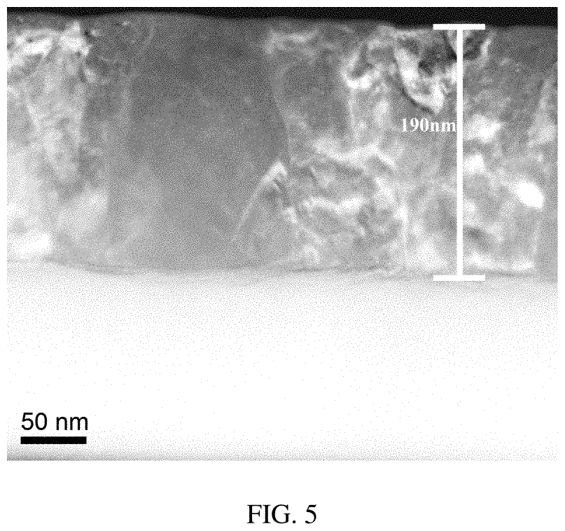

The grain size in each of the polycrystalline, ultrafine grain, and nanocrystalline films was determined using electron backscatter diffraction (EBSD) in the SEM and orientation maps obtained by NanoMEGAS ASTAR precession diffraction in the TEM (scanning electron microscopy), which also permits the behavior of the boundaries under irradiation to be correlated with mis-orientation. A cross-sectional view of the nanocrystalline iron film shows a columnar grain structure with random high angle grain boundaries and a grain diameter of 20-100 nm (FIG. 5).

### Example 4

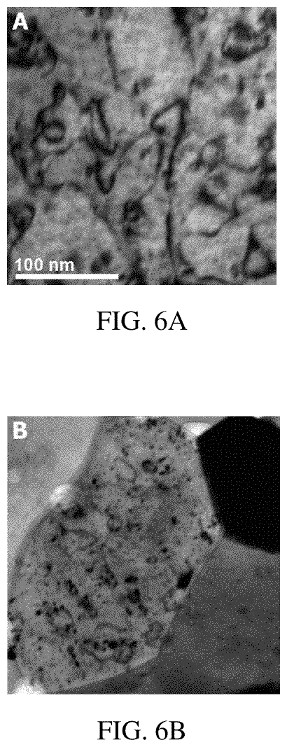

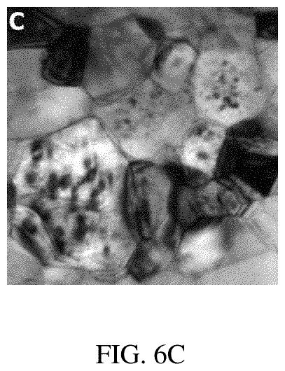

The materials produced in Example 3 were subjected to irradiation in situ at 300° C. using 1 MeV Kr²⁺ ions using a 650 KeV ion implanter directed into a Hitachi H-9000NAR TEM at an angle of 30° from the electron beam. Irradiation of the materials in each of the three grain size ranges showed that the density of grain boundaries in the materials has a dramatic effect on the level of damage caused by the radiation. In polycrystalline iron, irradiation at approximately 5 dpa caused the material to form a densely entangled dislocation network created by the interaction of growing finger type loops in regions thicker than 75 nm (FIG. 6A). In the 150 nm thick ultrafine grain iron films, the finger loops were visible but were significantly smaller in size (FIG. 6B). These finger loops have not grown large enough to form the tangled dislocation network that forms in polycrystalline iron. The effect of grain boundary sinks was more pronounced in nanocrystalline iron films of the same thickness. Dislocation loop diameter decreased to a minimum loop size of 3-5 nm in the nanocrystalline films with grain size less than 100 nm (FIG. 6C).

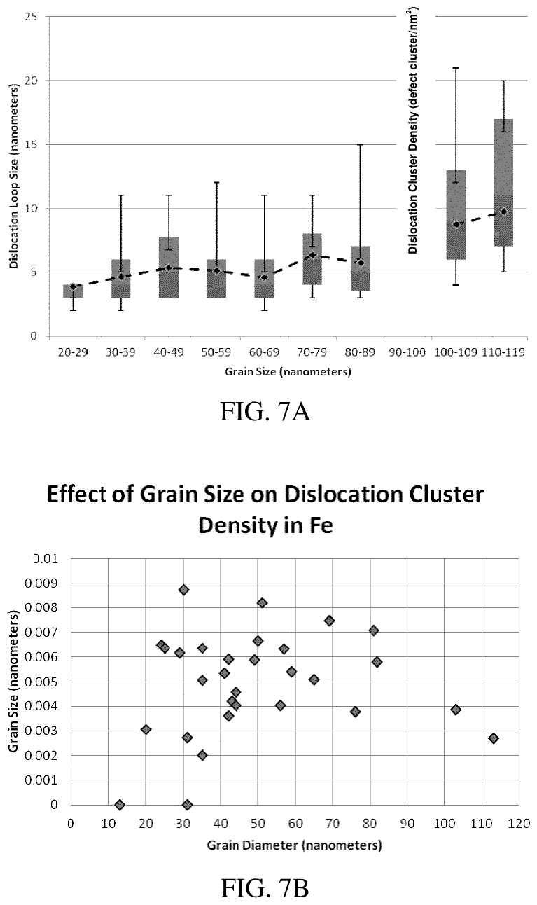

It was observed that the dislocation loop size in a nanocrystalline ion film after exposure to radiation is clearly impacted by the grain size in the iron films (FIG. 7A). As the grain size increases, the size of the dislocation loop clearly trends upwardly, indicating a poorer resistance to radiation damages. The dislocation loop density is also impacted by the grain size in the nanocrystalline iron films, though less prominently (FIG. 7B). At the largest grain sizes (˜100 nm), the dislocation loop density was low and the average size of the dislocation loops was relatively large, indicating the presence of the finger type loops. For nanocrystalline films with intermediate grain sizes (25-75 nm), the density of dislocation loops was higher and there was a significant amount of scatter. The average size of the dislocation loops (3-12 nm) was much smaller than in nanocrystalline films with grain size larger than 80 nm. For nanocrystalline films with grain size below 25 nm, the dislocation loop density decreased further, and the point defect clusters were even smaller in size (2-4 nm).

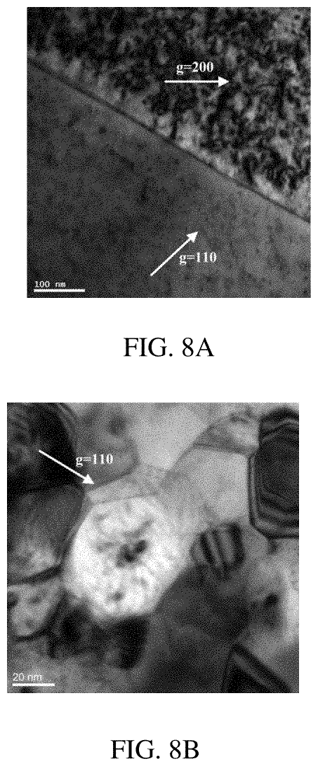

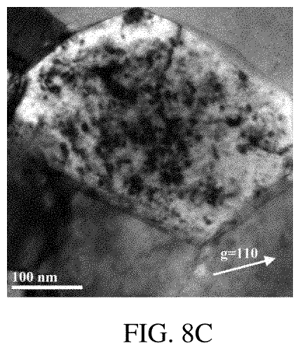

The denuded zone in these materials (polycrystalline, ultrafine grain, and nanocrystalline iron films) was also observed to be impacted by the grain size in these materials, as shown in FIGS. 8A-8C. For polycrystalline ion films, the grain boundary has an asymmetric denuded zone with an apparent width of approximately 15 nm on one side of the boundary and 30 nm on the other (FIG. 8A). In the ultrafine grain ion films (FIG. 8B) and nanocrystalline grain ion films (FIG. 8C), the width of the region with low defect density is similar to the denuded zone observed in bulk iron (˜30 nm). The result indicates that, as the grain size decreases, the denuded zone comprises a larger portion of the grain and the average defect density is greatly reduced.

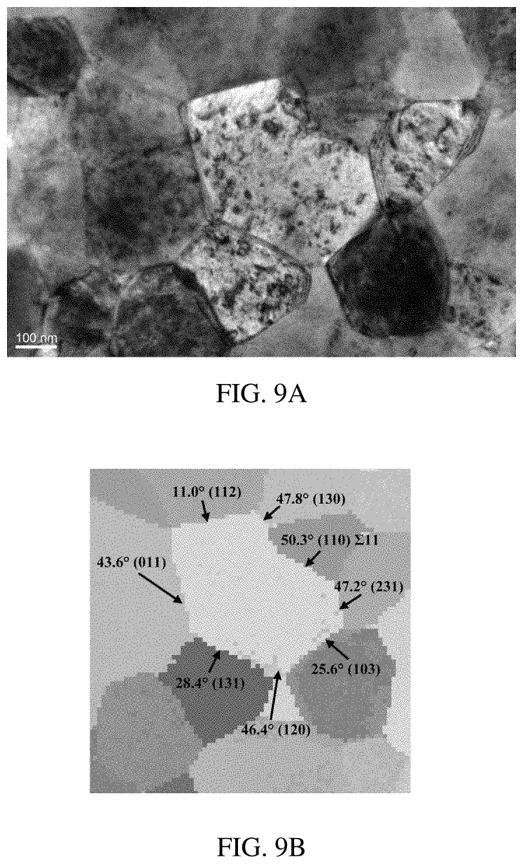

By correlating misorientation information with brightfield TEM images, a direct correlation was observed between grain boundary character and the width of the denuded zone, and therefore the ability to resist radiation damage. FIGS. 9A-9B highlight a grain in which each boundary had a different width to its denuded zone. Most of the boundaries in the grain were high angle boundaries and had very narrow denuded zones after irradiation. However, the boundary at the top of the grain has a denuded zone that was a low angle boundary (11.0° <112>) with a very wide denuded zone.

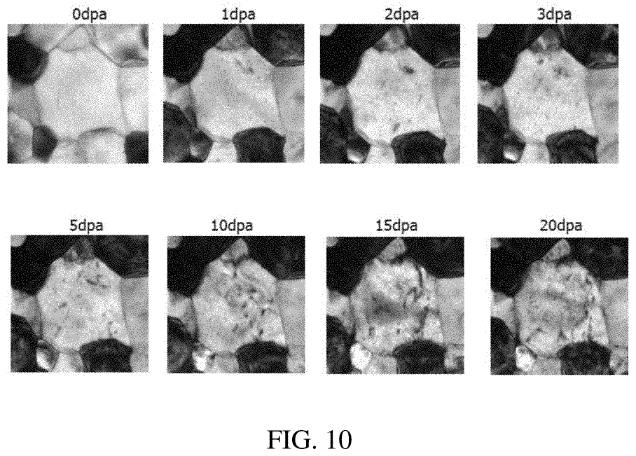

The contribution from the grain boundaries to the radiation tolerance of the nanocrystalline material was still significant even at high doses of radiation. Nanocrystalline ion films were exposed to irradiation at different dosages (from 1 dpa to 20 dpa) and radiation damages were measured using TEM (FIG. 10). It was observed that radiation damages were significantly lower with smaller grain size. For example, at 20 dpa, the amount of damages seen in the nanocrystalline material was less than that found after 5 dpa in a typical polycrystalline iron.

### Example 5

In this example, iron was deposited onto (100) NaCl substrates. The iron used in the deposition process was vaporized from an iron film with minor impurities in the amounts shown in Table 1.

TABLE 1
Impurities in the Iron Film (ppm by weight)

| Cr | Ni | Mo | Mn | Si | Cu | Ti | Al | Nb | Zr | V | W | Sn | S | C | B | N | O |
|---|---|---|---|---|---|---|---|---|---|---|---|---|---|---|---|---|---|
| 3.8 | 12 | 0.34 | 1.5 | 44 | 1.2 | 0.54 | 10 | <1 | <1 | 0.04 | 0.05 | 0.05 | 7 | 27 | 3.5 | 1 | 84 |

The iron was deposited on the substrate by direct current magnetron sputtering using the parameters listed in Table 2. A total of four depositions were carried out. The inert gas in the deposition chamber was argon.

TABLE 2
Depositions

| Sample | Deposition A | Deposition B | Deposition C | Deposition D |
|---|---|---|---|---|
| Sputtering Power (W) | 500 | 400 | 400 | 400 |
| Power Bias (W) | 40 | 25 | 25 | 25 |
| Chamber Pressure (mTorr) | 2 | 4 | 4 | 4 |
| Ar Gas flow at Target (sccm) | 30 | 30 | 30 | 30 |
| Ar Gas flow at Substrate | 4 | 0 | 0 | 3 |
| (sccm) | | | | |
| Deposition time (sec) | 270 | 270 | 270 | 270 |
| Substrate Temperature (° C.) | 370 | 370 | 370 | 370 |
| Substrate Condition | Good | Bad | Good | Good |

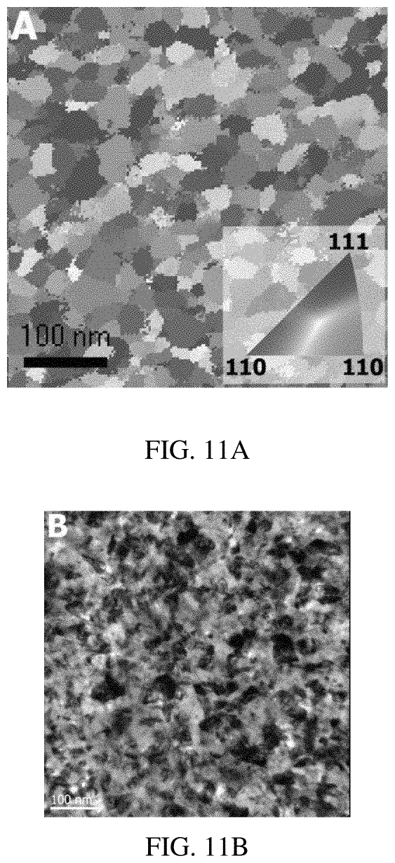

The microstructure produced using the parameters of Deposition B was the classic zone T or transition zone that consists of randomly oriented small seed crystals near the iron-NaCl interface and columnar grains growing from these nuclei. This microstructure of Deposition B was nanocrystalline with no preferred texture (FIGS. 11A-11B). When removed from the salt substrate and annealed at ˜600° C. in-situ in a TEM, the small equiaxed grains at the base of the columnar grains were annealed out, leaving a fully columnar structure with random texture. As a result, the film contained a significant volume density of random high angle grain boundaries.

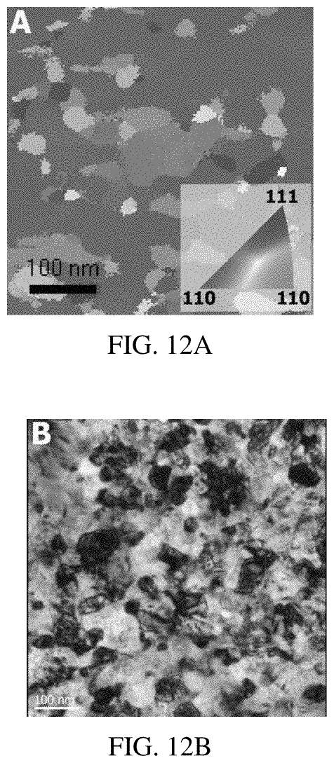

The microstructure produced using the parameters of Deposition C has large regions of nearly epitaxial film (shown as red in FIGS. 12A-12B) consisting of nanocrystalline grains having orientations with deviations of less than 5° from (100) NaCl.

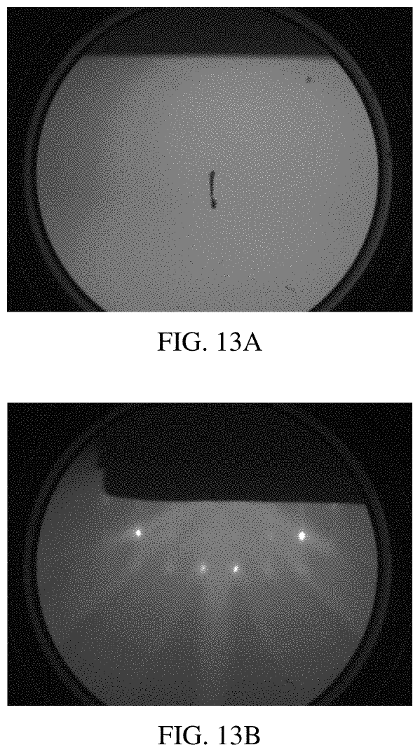

FIG. 13A shows a reflection high-energy electron diffraction (RHEED) pattern of polished (100) NaCl substrate. Only faint rings were observed with no sign of the rock salt structure. The surface condition of the NaCl substrate can be substantially improved using energetic ion bombardment prior to deposition. The NaCl substrate may be treated with a 450° C. anneal and bombardment with argon ions before deposition. The treated NaCl substrate has a RHEED pattern showing the expected (100) rock salt structure (FIG. 13B).

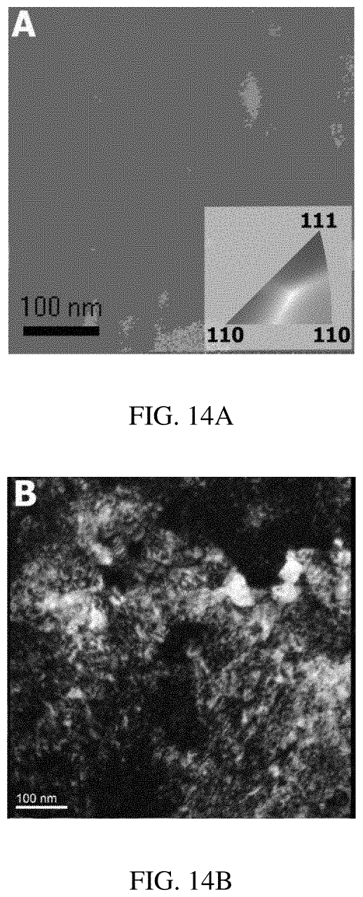

The microstructure produced by depositing iron on the cleaned NaCl substrate (from FIG. 13B) is shown in FIGS. 14A-14B. The substrate was subjected to 3 sccm of Argon for 30 seconds prior to opening the shutter to begin the deposition. The Argon gas flow was maintained throughout the deposition which produced very strong epitaxy between the nanocrystalline microstructure and substrate (FIGS. 14A-14B).

The microstructure shows a very strong (100) NaCl texture. This structure is typically reported in literature as single crystal based on the appearance of a strong crystalline diffraction pattern. Through brightfield TEM (FIG. 14B) and orientation mapping (FIG. 14A), the microstructure was found to be polycrystalline and dominated by low angle grain boundaries, the majority of which exhibit primarily tilt misorientation. Some regions appear to retain a nanocrystalline microstructure with a mixture of low angle grain boundaries and a few random high angle boundaries where the odd grain nucleated in a random orientation.

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meanings of the terms in which the appended claims are expressed.

1-18. (canceled)

19. A process for producing a radiation resistant nanocrystalline material that has a polycrystalline microstructure from a starting material selected from the group consisting of Cr, Ni, Mn, P, S, Si, Co, Al, Zr, Hf, W, Fe, Fe—Zr, Cu, Cu—Ni, Cu—Li, Al—Li, Mo—Re, Fe—Cr—Ni, austenitic stainless steel, zirconium alloys and nickel based alloys, the process comprising a step of:
depositing the starting material by physical vapor deposition onto a substrate that is maintained at a substrate temperature of from about 20° C. to about 850° C. to produce the nanocrystalline material,
wherein the physical vapor deposition is performed in an inert gas atmosphere and a gas flow in a range of from about 10 sccm to about 50 sccm is maintained at a surface of the starting material during the deposition step.

20. The process of claim 19, wherein the substrate is selected from the group consisting of carbides, ceramics, silicon, ionic materials, polymers, oxides, metals, and salts.

21. The process of claim 19, wherein the substrate temperature is from about 100° C. to about 700° C.

22. The process of claim 19, wherein the physical vapor deposition is magnetron sputtering deposition.

23. The process of claim 22, wherein the magnetron sputtering deposition uses a direct current power with a sputtering power in a range of from about 50 Watts to about 600 Watts.

24. The process of claim 22, wherein the magnetron sputtering deposition uses a radio frequency power with a sputtering power in a range of from about 20 Watts to about 300 Watts.

25. The process of claim 22, wherein the magnetron sputtering deposition uses a sputtering bias in a range from about 1 Watt to about 5 Watts.

26. The process of claim 19, further comprising the steps of:
heating the nanocrystalline material to an annealing temperature of from about 450° C. to about 800° C. at a rate of temperature increase from about 2° C./minute to about 50° C./minute; and
maintaining the nanocrystalline material at the annealing temperature of from about 450° C. to about 800 C for a period from about 5 to about 35 minutes.

27. The process of claim 26, wherein the heating and maintaining steps are carried out in an atmosphere comprising endothermic gas, hydrogen gas, nitrogen gas, or a combination thereof.

28. The process of claim 26, further comprising the step of cooling the nanocrystalline material after the maintaining step at a rate of temperature decrease of from about 5° C./minute to about 30° C./minute.

29. The process of claim 28, wherein the nanocrystalline material is cooled to a temperature of from about 250° C. to about 350° C.

30. The process of claim 28, wherein the rate of temperature decrease during the cooling step is from about 10° C./minute to about 50° C./minute.

31. The process of claim 19, wherein the physical vapor deposition is selected from the group consisting of electron beam physical vapor deposition, magnetron sputtering physical vapor deposition, pulsed laser physical vapor deposition, thermal evaporation physical vapor deposition, and any combination thereof.

32. The process of claim 19, wherein during the physical vapor deposition step, there is a growth rate of a film of the nanocrystalline material of from about 0.5 Å/second to about 5 Å/second.

33. A nanocrystalline material prepared by the process of claim 19.

34. A process for producing a radiation resistant nanocrystalline material that has a polycrystalline microstructure from a starting material selected from the group consisting of Cr, Ni, Mn, P, S, Si, Co, Al, Zr, Hf, W, Fe, Fe—Zr, Cu, Cu—Ni, Cu—Li, Al—Li, Mo—Re, Fe—Cr—Ni, austenitic stainless steel, zirconium alloys and nickel based alloys, the process comprising a step of:
depositing the starting material by physical vapor deposition onto a substrate that is maintained at a substrate temperature of from about 20° C. to about 850° C. to produce the nanocrystalline material,
wherein the physical vapor deposition is magnetron sputtering deposition and
a) the magnetron sputtering deposition uses a direct current power with a sputtering power in a range of from about 50 Watts to about 600 Watts, or
b) the magnetron sputtering deposition uses a radio frequency power with a sputtering power in a range of from about 20 Watts to about 300 Watts, or
c) the magnetron sputtering deposition uses a sputtering bias in a range from about 1 Watt to about 5 Watts.

35. A nanocrystalline material prepared by the process of claim 34.

36. The process of claim 19, wherein the polycrystalline microstructure comprises high angle boundaries and low angle grain boundaries, the high angle boundaries and low angle grain boundaries have denuded zones, and the low angle grain boundaries have wider denuded zones than the denuded zones of the high angle grain boundaries.

37. A process for producing a radiation resistant nanocrystalline material that has a polycrystalline microstructure from a starting material selected from the group consisting of carbides, ceramics, silicon, ionic materials, polymers, oxides, metals, metal alloys and salts, the process comprising steps of:
depositing the starting material by physical vapor deposition onto a substrate that is maintained at a substrate temperature of from about 20° C. to about 850° C. to produce the nanocrystalline material,
wherein the polycrystalline microstructure comprises high angle boundaries and low angle grain boundaries, the high angle boundaries and low angle grain boundaries have denuded zones, and the low angle grain boundaries have wider denuded zones than the denuded zones of the high angle grain boundaries.

38. A nanocrystalline material prepared by the process of claim 37.
